(19) United States
(12) Patent Application Publication
(10) Pub. No.: US 2003/0035377 A1
(43) Pub. Date: Feb. 20, 2003

(54) Method and apparatus for performing dying gasp process for an external digital subscriber line communication terminal

(76) Inventor: Dong-Kweon Ju, Suwon-shi (KR)

Correspondence Address: Robert E. Bushnell, Suite 300, 1522 K Street, N.W., Washington, DC, 20005, US

(21) Appl. No.: 10/140,289

(22) Filed: May 8, 2002

(30) Foreign Application Priority Data
Aug. 16, 2001 (KR) 2001-49232

(51) Int. Cl. G01R 31/08; G06F 15/173

(52) U.S. Cl. 370/245; 709/224

(57) ABSTRACT

A method and apparatus accurately and reliably perform a dying gasp process for an external digital subscriber line communication terminal connected to a personal computer via the Ethernet. The state of an Ethernet port of the communication terminal connectable to the personal computer is sensed, and whether the Ethernet port is made inactive after the Ethernet port is made active is checked. The dying gasp process is performed upon sensing the occurrence of the inactive state of the Ethernet port after the Ethernet port is made active.

### CLAIM OF PRIORITY

This application claims priority to an application entitled “METHOD AND APPARATUS FOR PERFORMING DYING GASP PROCESS OF EXTERNAL DIGITAL SUBSCRIBER LINE COMMUNICATION TERMINAL”, filed in the Korean Industrial Property Office on Aug. 16,2001 and assigned Serial No. 2001-49232, the contents of which are hereby incorporated by reference.

### BACKGROUND OF THE INVENTION

1. Technical Field

The present invention relates to a digital subscriber line communication terminal and, more particularly, to a method and apparatus for performing a dying gasp process for an external digital subscriber line communication terminal that is connected to a personal computer (PC) via the is Ethernet.

2. Description of the Related Art

A digital subscriber line, typically denoted by “xDSL”, relates to a high-speed modem technique that is being developed to meet the market demand for large-scale high-speed Internet access. The digital subscriber line also relates to a public network technique that supports a broad bandwidth at a limited distance using an existing copper telephone wire (twisted pair wire). This xDSL involves various kinds of techniques, such as an asymmetric digital subscriber line (ADSL), a high-bit-rate DSL (HDSL), a single-line DSL (SDSL), a single-pair high-speed SDSL (SHDSL), a very-high-data-rate DSL (VDSL), and so forth.

In an ADSL network model of the xDSL, an ADSL transceiver unit-central (ATU-C) in a central office and an ADSL transceiver unit-remote (ATU-R) in a subscriber branch are interconnected via an ADSL using an existing telephone wire. Also, the ATU-C is connected to a network, and the ATU-R is connected to a PC via an Ethernet link. The Ethernet link is provided by local area network (LAN) interface logic in the ATU-R, a LAN card in the PC, and a LAN cable interconnecting them.

A user of the PC can gain access to the network (for example, the Internet) via the ATU-R, the ADSL and the ATU-C. The ATU-R used for Internet access by the PC user in the ADSL network is so-called customer premise equipment (CPE) that is an external xDSL communication terminal.

While maintaining the ADSL connection in the above manner, the CPE may perform a dying gasp process to terminate the ADSL connection due to, for example, the ending of Internet use by the user. The dying gasp signifies that the CPE sends a connection release message to a central system, as prescribed in ANSI T1.413, ITU-T 992.2 and ITU-T 992.1.

A dying gasp processor of the CPE comprises a sensing circuit for generating an interrupt signal upon sensing a turned-off state of the CPE, and a CPE controller or central processing unit (CPU) for performing the dying gasp process in response to the interrupt signal from the sensing circuit. LAN interface logic is connected to the CPU and also, via the LAN cable, to the LAN card so as to provide the Ethernet link as stated previously. An input voltage is supplied to the CPE as an operating voltage to each component in the CPE through a capacitor, a diode and another capacitor. The sensing circuit includes an operational amplifier and resistors, and is connected between an input voltage source and the CPU. The operational amplifier has a non-inverting input terminal (+) connected to the input voltage source through the capacitor, an inverting input terminal (−) connected to ground through a first resistor, and an output terminal connected to the inverting input terminal (−) through a second resistor. When the input voltage falls below a predetermined level as the CPE is turned off, the operational amplifier generates an interrupt signal of logic “low”, and applies the generated interrupt signal to the CPU. Subsequently, in response to the interrupt signal from the operational amplifier, the CPU is interrupted so as to perform the dying gasp process. At this time, even though the CPE is turned off, the operating voltage continues to be supplied to the CPU due to charging voltages on the capacitors and, for a certain period of time, is required for the dying gasp process.

As mentioned above, the dying gasp processor performs the dying gasp process by sensing, in a hardware manner, the moment when the CPE is turned off. That is, the processor has to sense the moment that the level of the input voltage drops, resulting in a reduction in accuracy of the dying gasp process. Further, the dying gasp process cannot be carried out when the user disconnects the xDSL connection under the condition that the CPE is not turned off. Furthermore, an additional hardware module, or sensing circuit, is required to sense the moment that the CPE is turned off.

The following are considered to be generally pertinent to the present invention but are burdened by the disadvantages set forth above:

U.S. Pat. No. 5,255,317 to Arai et al., which discloses a subscriber line interface circuit for serving ISDN subscribers using echo cancellers and POTS subscribers, issued Oct. 19, 1993;

U.S. Pat. No. 5,408,260 to Amon, which discloses a customer premises ADSL signal distribution arrangement, issued Apr. 18, 1995;

U.S. Pat. No. 5,410,343 to Coddington et al., which discloses a video-on-demand services using public switched telephone network, issued Apr. 25, 1995;

U.S. Pat. No. 5,461,616 to Suzuki, which discloses an asymmetric digital subscriber line control system, issued Oct. 24, 1995;

U.S. Pat. No. 5,519,731 to Cioffi, which discloses an ADSL compatible discrete multi-tone apparatus for mitigation of T1 noise;

U.S. Pat. No. 5,771,279 to Cheston, III et al., which discloses an advanced intelligent network interacting with customer premises equipment, issued Jun. 23, 1998;

U.S. Pat. No. 5,754,555 to Hurme et al, which discloses a subscriber network arrangement for connecting subscribers to a telephone network, issued May 19, 1998;

U.S. Pat. No. 5,889,856 to O'Toole et al., which discloses an ADSL integrated line card with digital splitter and POTS CODEC without bulky analog splitter, issued May 30, 1999;

U.S. Pat. No. 6,263,016 to Bellenger et al., which discloses methods for interfacing a subscriber link to digital networks, issued Jul. 17, 2001;

U.S. Pat. No.6,272,209 to Bridger et al., which discloses a lifeline telephony provision for voice over digital subscriber line; and

U.S. Pat. No. 6,324,212 to Jenness, which discloses an apparatus using low spectrum selectively for proving both ADSL and POTS service, issued Nov. 27, 2001.

### SUMMARY OF THE INVENTION

Therefore, the present invention has been developed in view of the above problems, and it is an object of the present invention to provide a method and apparatus for performing a dying gasp process accurately and reliably.

It is another object of the present invention to provide a method and apparatus for performing a dying gasp process without using additional hardware.

In accordance with the present invention, the above and other objects can be accomplished by the provision of a method and apparatus for accurately and reliably performing a dying gasp process for an external digital subscriber line communication terminal that is connected to a personal computer via the Ethernet. The state of an Ethernet port of the communication terminal connectable to the personal computer is sensed, and whether the Ethernet port is made inactive is checked after the Ethernet port is made active. The dying gasp process is performed upon sensing the inactive state of the Ethernet port after the Ethernet port is made active.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference numerals indicate the same or similar components, and wherein:

FIG. 1 is a schematic view of a typical ADSL network model;

FIG. 2 is a circuit diagram of a dying gasp processor of a CPE;

FIG. 3 is a block diagram showing the construction of a dying gasp processor of a CPE in accordance with the present invention; and

FIG. 4 is a flowchart illustrating the operation of the dying gasp processor of FIG. 3.

### DETAILED DESCRIPTION OF THE PREFERRED EMBODIMENTS

Preferred embodiments of the present invention will now be described in detail with reference to the annexed drawings. In the following description, a detailed description of known functions and configurations incorporated herein will be omitted when it may make the subject matter of the present invention rather unclear.

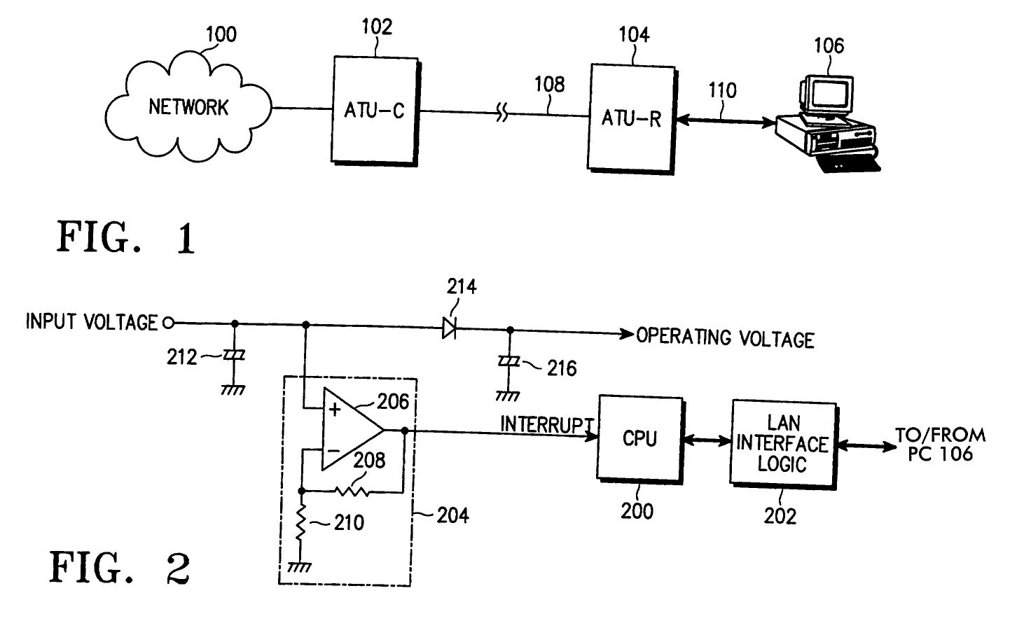

FIG. 1 schematically shows the construction of an ADSL network model as an example of the xDSL. As shown in this drawing, an ATU-C 102 in a central office and an ATU-R 104 in a subscriber branch are interconnected via an ADSL 108 using an existing telephone wire. Also, the ATU-C 102 is connected to a network 100, and the ATU-R 104 is connected to a PC 106 via an Ethernet link 110. The Ethernet link 110 is provided by local area network (LAN) interface logic (not shown) in the ATU-R 104, a LAN card (not shown) in the PC 106, and a LAN cable interconnecting them.

A user of the PC 106 can gain access to the network 100 (for example, the Internet) via the ATU-R 104, the ADSL 108 and the ATU-C 102. The ATU-R 104 used for Internet access by the use of PC 106 in the ADSL network is the so-called CPE, which is an external xDSL communication terminal.

While maintaining the ADSL connection in the above manner, the CPE may perform a dying gasp process to terminate the ADSL connection due to, for example, the ending of the Internet use by the user. The dying gasp signifies that the CPE sends a connection release message to a central system, as prescribed in ANSI T1.413, ITU-T 992.2 and ITU-T 992.1.

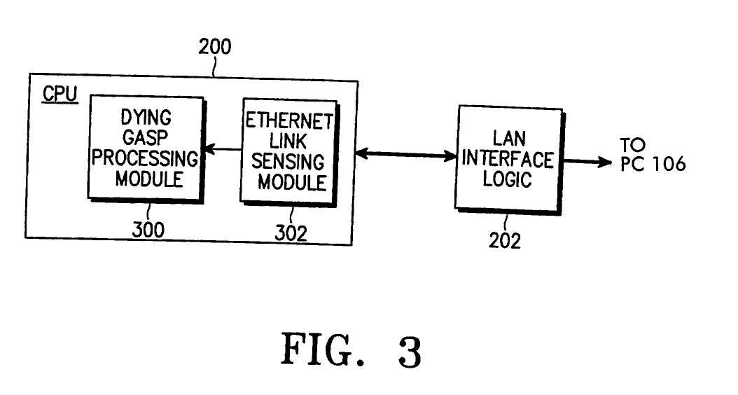

FIG. 2 is a circuit diagram of a dying gasp processor of the CPE. As shown in this drawing, the dying gasp processor comprises a sensing circuit 204 for generating an interrupt signal upon sensing a turned-off state of the CPE, and a CPE controller or central processing unit (CPU) 200 for performing a dying gasp process in response to the interrupt signal from the sensing circuit 204. LAN interface logic 202 is connected to the CPU 200 and also, via a LAN cable, to the LAN card in the PC 106 of FIG. 1 so as to provide the Ethernet link as stated previously. An input voltage to the CPE is supplied as an operating voltage to each component in the CPE through a capacitor 212, diode 214 and capacitor 216. The sensing circuit 204 includes an operational amplifier 206 and resistors 208 and 210 connected between an input voltage source and the CPU 200. The operational amplifier 206 has a non-inverting input terminal (+) connected to the input voltage source through the capacitor 212, an inverting input terminal (−) connected to ground through the resistor 210, and an output terminal connected to the inverting input terminal (−) through the resistor 208. When the input voltage falls below a predetermined level as the CPE is turned off, the operational amplifier 206 generates an interrupt signal of logic “low”, and applies the generated interrupt signal to the CPU 200. Subsequently, the CPU 200 is interrupted in response to the interrupt signal from the operational amplifier 206 so as to perform the dying gasp process. At this time, even though the CPE is turned off, the operating voltage continues to be supplied to the CPU 200, owing to charging voltages on the capacitors 212 and 216, for a certain period of time required for the dying gasp process.

As mentioned above, the dying gasp processor performs the dying gasp process by sensing, in a hardware manner, the moment that the CPE is turned off. That is, the processor has to sense the moment that the level of the input voltage drops, resulting in a reduction in accuracy of the dying gasp process. Further, the dying gasp process cannot be carried out when the user disconnects the xDSL connection under the condition that the CPE is not turned off. Furthermore, an additional hardware module, or sensing circuit, is required to sense the moment that the CPE is turned off.

FIG. 3 is a block diagram showing the construction of a dying gasp processor of a CPE in accordance with the present invention. With reference to FIG. 3, there is shown in block form the construction of a dying gasp processor of a CPE in accordance with the present invention. The CPU 200, which is the CPE controller connected to the LAN interface logic 202 as described previously with reference to FIG. 2, includes an Ethernet link sensing module 302 and a dying gasp processing module 300. The Ethernet link sensing module 302 and dying gasp processing module 300 are software modules executed by the CPU 200 in the typical CPE. Typically, the Ethernet link sensing module 302 functions to sense the state of an Ethernet port of the LAN interface logic 202, and the dying gasp processing module 300 functions to perform a dying gasp process.

If the user turns on the PC 106 as shown in FIG. 1 to use the xDSL, then the PC 106 is connected to the CPE via the Ethernet link 110, thereby causing the Ethernet port to be made active. Thereafter, if the user ends the xDSL use and turns off the PC 106, then the connection between the PC 106 and the CPE via the Ethernet link 110 is released, thus making the Ethernet port inactive. According to the present invention, the dying gasp processor performs the dying gasp process using the fact that the Ethernet port is made inactive as the PC 106 and the Ethernet of the CPE are electrically isolated from each other.

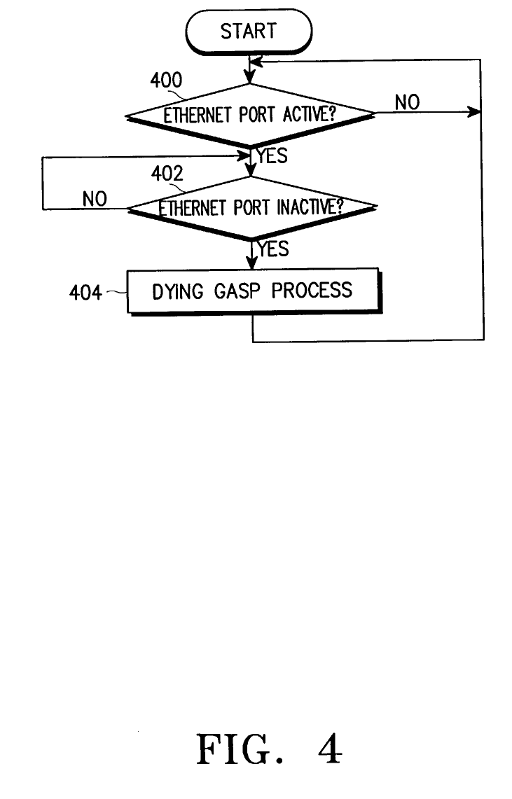

A detailed description will hereinafter be given of the operation of the dying gasp processor with the above-stated construction in accordance with the present invention in conjunction with steps 400-404 in FIG. 4, which is a flowchart illustrating the operation of the dying gasp processor of FIG. 3. When the connection between the PC 106 and the CPE via the Ethernet link 110 is established in response to the turned-on state of the PC 106 and the Ethernet port is thus made active, then the Ethernet link sensing module 302 senses the active state of the Ethernet port at step 400, and checks at step 402 whether the Ethernet port is made inactive. Thereafter, if the user ends the xDSL use and turns off the PC 106, then the connection between the PC 106 and the CPE via the Ethernet link 110 is released, thus making the Ethernet port inactive. The Ethernet link sensing module 302 senses the inactive state of the Ethernet port at step 402, and notifies the dying gasp processing module 300 of the sensed inactive state at step 404. As a result, the dying gasp processing module 300 performs the dying gasp process in response to the inactive state of the Ethernet port.

As is apparent from the above description, according to the present invention, the dying gasp processor can accurately perform the dying gasp process by sensing, on the basis of the inactivation of the Ethernet port, the moment that the PC 106 and the CPE are electrically isolated from each other. Further, the dying gasp process can be carried out even when the user disconnects the xDSL connection under the condition that the CPE is not turned off. Furthermore, the dying gasp process is performed by the sensing of the inactive state of the Ethernet port by the Ethernet link sensing module 300, which is used in the typical CPE to sense the Ethernet port state. As a result, there is no need for additional hardware required to sense the moment that the CPE is turned off.

Although the preferred embodiments of the present invention have been disclosed for illustrative purposes, those skilled in the art will appreciate that various modifications, additions and substitutions are possible without departing from the scope and spirit of the invention as disclosed in the accompanying claims. For example, the PC 106 and the CPE may be interconnected via a universal serial bus (USB) although they have been disclosed herein as being interconnected via the Ethernet.

What is claimed is:

1. A method for performing a dying gasp process for an external digital subscriber line (DSL) communication terminal connected to a personal computer via an Ethernet, comprising the steps of:
a) sensing a state of an Ethernet port of said DSL communication terminal connectable to said personal computer;
b) checking whether said Ethernet port of said external DSL communication terminal is made inactive after said Ethernet port of said external DSL communication terminal is made active; and
c) performing the dying gasp process upon sensing the inactive state of said Ethernet port of said external DSL communication terminal after said Ethernet port of said external DSL communication terminal is made active.

2. The method as set forth in claim 1, wherein said Ethernet port of said external DSL communication terminal is made active when it is connected to said personal computer via the Ethernet as said personal computer is turned on, and said Ethernet port of said external DSL communication terminal is made inactive when a connection thereof to said personal computer via the Ethernet is released as said personal computer is turned off.

3. An apparatus for performing a dying gasp process for an external digital subscriber line (DSL) communication terminal connected to a personal computer via an Ethernet, comprising:
local area network (LAN) interface logic for providing an Ethernet link to said personal computer; and
a control unit connected to said LAN interface logic, said control unit including an Ethernet link sensing means for sensing a state of an Ethernet port of said LAN interface logic connectable to said personal computer, and dying gasp processing means for performing the dying gasp process, said Ethernet link sensing means notifying said dying gasp processing means of an inactive state of said Ethernet port of said LAN interface logic upon sensing the inactive state of said Ethernet port of said LAN interface logic after said Ethernet port of said LAN interface logic is made active, said dying gasp processing means performing said dying gasp process in response to notification from said Ethernet link sensing means.

4. The apparatus as set forth in claim 3, wherein said Ethernet port of said LAN interface logic is made active when it is connected to said personal computer via the Ethernet as said personal computer is turned on, and is made inactive when a connection of said Ethernet port of said LAN interface logic to said personal computer via the Ethernet is released as said personal computer is turned off.

5. The apparatus as set forth in claim 3, wherein said Ethernet link sensing means and said dying gasp processing means comprise respective software modules.

6. The apparatus as set forth in claim 3, further comprising a sensing circuit connected between an input voltage source and said dying gasp processing means for providing an interrupt signal to said dying gasp processing means upon sensing a turned-off state of the external DSL communication terminal.

7. The apparatus as set forth in claim 6, wherein said sensing circuit comprises an operational amplifier having a non-inverting input connected to the input voltage source, an inverting input connected to ground via a first resistor, and an output connected to said dying gasp processing means, and connected to said inverting input and to said first resistor via a second resistor.

8. A method for performing a dying gasp process for an external digital subscriber line (DSL) communication terminal connected to a personal computer via an Ethernet, comprising the steps of:
a) determining whether an Ethernet port of said external DSL communication terminal is in an active state;
b) when it is determined in step (a) that said Ethernet port of said external DSL communication terminal is in the active state, determining whether said Ethernet port of said external DSL communication terminal is made inactive; and
c) performing the dying gasp process upon determining in step (b) that said Ethernet port of said external DSL communication terminal is made inactive.

9. The method as set forth in claim 8, wherein said Ethernet port of said external DSL communication terminal is made active when it is connected to said personal computer via the Ethernet as said personal computer is turned on, and said Ethernet port of said external DSL communication terminal is made inactive when a connection thereof to said personal computer via the Ethernet is released as said personal computer is turned off.

10. An apparatus for performing a dying gasp process for an external digital subscriber line (DSL) communication terminal connected to a personal computer via an Ethernet, comprising:
means for providing an Ethernet link to said personal computer; and
a control unit connected to said LAN interface logic, said control unit including an Ethernet link sensing means for sensing a state of an Ethernet port, and dying gasp processing means for performing the dying gasp process, said Ethernet link sensing means notifying said dying gasp processing means of an inactive state of said Ethernet port upon sensing the inactive state of said Ethernet port after said Ethernet port is made active, said dying gasp processing means performing said dying gasp process in response to notification from said Ethernet link sensing means.

11. The apparatus as set forth in claim 10, wherein said Ethernet port is made active when said Ethernet port is connected to said personal computer via the Ethernet as said personal computer is turned on, and is made inactive when a connection of said Ethernet port to said personal computer via the Ethernet is released as said personal computer is turned off.

12. The apparatus as set forth in claim 10, wherein said Ethernet link sensing means and said dying gasp processing means comprise respective software modules.

13. The apparatus as set forth in claim 10, further comprising a sensing circuit connected between an input voltage source and said dying gasp processing means for providing an interrupt signal to said dying gasp processing means upon sensing a turned-off state of the external DSL communication terminal.

14. The apparatus as set forth in claim 13, wherein said sensing circuit comprises an operational amplifier having a non-inverting input connected to the input voltage source, an inverting input connected to ground via a first resistor, and an output connected to said dying gasp processing means, and connected to said inverting input and to said first resistor via a second resistor.
